(19) United States
(12) Patent Application Publication
(10) Pub. No.: US 2024/0243182 A1
(43) Pub. Date: Jul. 18, 2024

(54) MICROELECTRONIC DEVICE AND METHOD OF FORMING

(71) Applicant: Tokyo Electron Limited, Tokyo (JP)

(72) Inventors: H. Jim Fulford, Marianna, FL (US); Mark I. Gardner, Cedar Creek, TX (US)

(21) Appl. No.: 18/527,484

(22) Filed: Dec. 4, 2023

Related U.S. Application Data
(60) Provisional application No. 63/439,380, filed on Jan. 17, 2023.

(51) Int. Cl. H01L 29/423; H01L 21/8234; H01L 27/06; H01L 29/06; H01L 29/417; H01L 29/66; H01L 29/775; H01L 29/786

(52) U.S. Cl. CPC H01L 29/42392; H01L 21/823412; H01L 21/823418; H01L 27/0629; H01L 29/0673; H01L 29/41733; H01L 29/66439; H01L 29/775; H01L 29/78696

(57) ABSTRACT

In some implementations, the device may include a vertical transistor having a first source/drain (s/d) region adjacent a substrate, a channel region above the first s/d region, and a second s/d region. In addition, the device includes a capacitor having two conductive regions separated by a dielectric region, one of the two conductive regions electrically coupled to the second s/d region.

The present application claims the benefit of U.S. Provisional Application No. 63/439,380 filed on Jan. 17, 2023, which is incorporated herein by reference in its entirety.

In one general aspect, a microelectronic device may include a vertical transistor having a first source/drain (s/d) region adjacent a substrate, a channel region above the first s/d region, and a second s/d region. The microelectronic device may also include a capacitor having two conductive regions separated by a dielectric region, one of the two conductive regions electrically coupled to and, in some embodiments integral with, the second s/d region. Other embodiments of this invention include the method and apparatuses used to form such microelectronic devices. A microelectronic device may include a vertical transistor having a gate structure that extends around a portion of the channel region to form a gate all around (GAA) structure.

In one general aspect, a stack of microelectronic devices may be provided in the x, y and/or z directions to form a memory array of memory cells.

In one general aspect, a method may include forming a vertical transistor having a first source/drain (s/d) region adjacent a substrate, a channel region above the first s/d region, and a second s/d region. The method may also include forming a capacitor having two conductive regions separated by a dielectric region, one of the two conductive regions electrically coupled to the second s/d region. Other embodiments of this aspect include corresponding computer systems, apparatus, and computer programs recorded on one or more computer storage devices, each configured to perform the actions of the methods.

Implementations may include one or more of the following features. For example, a method of forming a vertical transistor may include forming a first s/d contact of the first s/d region, forming the channel region over the s/d contact, forming a gate structure in contact with the channel region, and forming a second s/d contact overlying and in contact with the channel region. Prior to forming the s/d contact, a routing layer may be formed in a dielectric to electrically connect the s/d contact to another device in a circuit. The channel region may include a semiconductive behaving oxide, a 2D material, an epitaxial semiconductive behaving material, or other suitable materials.

The channel region may be formed as a blanket channel layer, the channel layer patterned to form the channel region. An indent etch may then be performed to remove a portion of the channel region underlying a shaped dielectric spacer to form an opening. A gate dielectric and gate electrode are then deposited in the opening to form the gate structure.

A dielectric isolation layer may then be formed over the substrate and around the gate structure and dielectric spacer. Next, the dielectric spacer may be removed leaving a first opening overlying the channel region, after which an additional spacer may be formed on the dielectric isolation layer to define a second opening smaller than the first opening. The second s/d contact is then formed in the opening.

The capacitor formation may continue by forming a dielectric layer over the s/d contact, the second s/d contact integral with one of the two conductive regions of the capacitor. Next a conductive layer is formed over the dielectric layer, and the dielectric layer and conductive layer are patterned to form the dielectric region of the capacitor and the other of the two conductive regions of the capacitor.

Implementations of the described techniques may include hardware, a method or process, or a computer tangible medium.

### BRIEF DESCRIPTION OF THE DRAWINGS

FIG. 1 is a flow diagram illustrating a method according to certain embodiments.

FIG. 2 shows a schematic illustration of a microelectronic device according to certain embodiments.

FIG. 3A shows a schematic illustration of a stack of microelectronic devices according to certain embodiments.

FIG. 3B shows a schematic illustration of a stack of microelectronic devices according to certain embodiments.

FIGS. 4-15 show steps in a method of formation of a microelectronic device according to certain embodiments.

### DETAILED DESCRIPTION

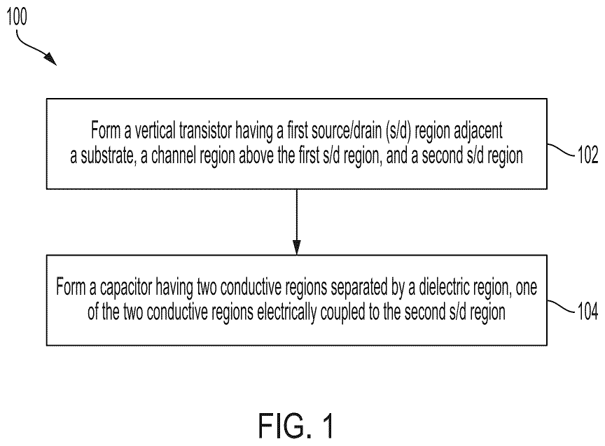

FIG. 1 is a flowchart of an example process 100. In some implementations, one or more process blocks of FIG. 1 may be performed by one or more semiconductor manufacturing apparatuses.

As shown in FIG. 1, a process 100 may include forming a vertical transistor having a first source/drain (s/d) region adjacent a substrate, forming a channel region above the first s/d region, and a second s/d region (block 102). For example, a vertical transistor may be formed having a first source/drain (s/d) region adjacent a substrate, a channel region above the first s/d region, and a second s/d region above the channel region, as described above. As also shown in FIG. 1, process 100 may include forming a capacitor having two conductive regions separated by a dielectric region, one of the two conductive regions electrically coupled to the second s/d region (block 104). For example, a capacitor may be formed having two conductive regions separated by a dielectric region, one of the two conductive regions electrically coupled to the second s/d region, wherein a s/d contact of the vertical transistor is integral with one of the two conductive regions.

Although FIG. 1 shows example blocks of process 100, in some implementations, process 100 may include additional blocks, fewer blocks, different blocks, or differently arranged blocks than those depicted in FIG. 1.

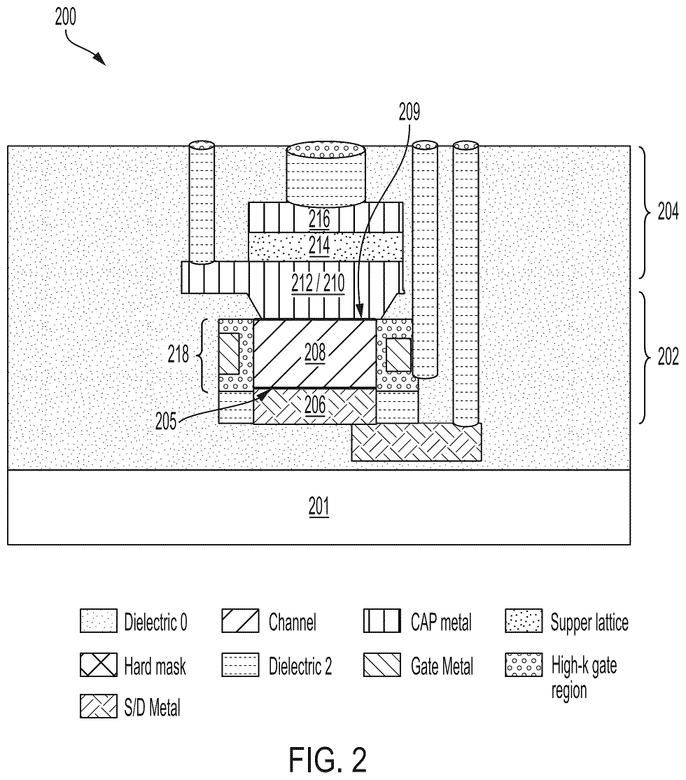

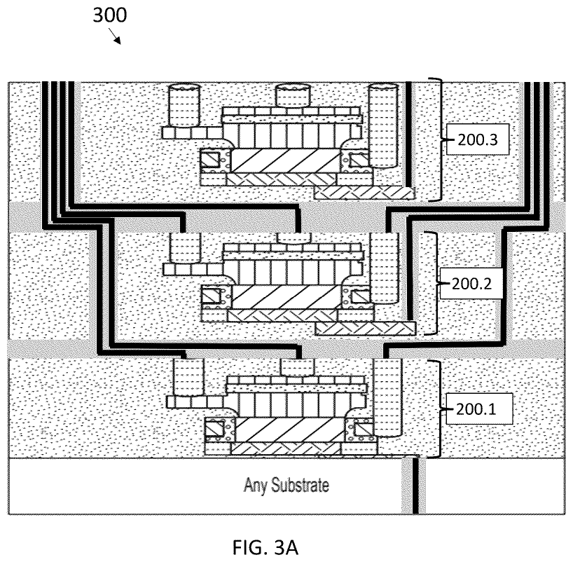

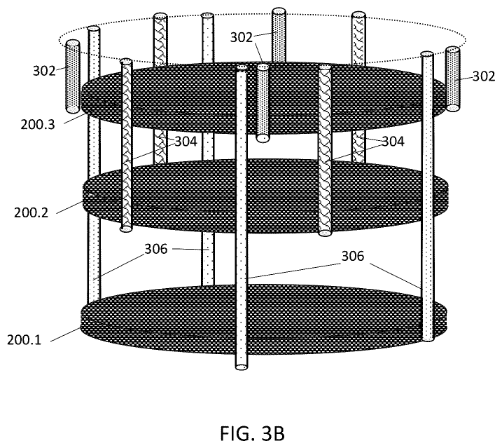

FIG. 2 shows a microelectronic device 200 that includes a vertical transistor 202 and a capacitor 204. The microelectronic device 200 may be a memory cell, which may be stacked into an array 300 as shown in FIG. 3A. While only one vertical stack is shown, it is understood that more devices 200 may be arranged in the x, y and z directions and electrically connected using conventional techniques to form a memory cell array. Moreover there may be any number of devices in each direction.

Each vertical transistor 202 has a first source/drain (s/d) region 205, including a s/d contact 206 adjacent a substrate 201. A channel region 208 is above the first s/d region 205. A second s/d region 209 is provided above the channel region 208 and includes a second s/d contact 210.

Each capacitor 204 has two conductive regions separated by a dielectric region. A first conductive region 212 is integral with the s/d contact 210. A dielectric 214 separates the first conductive region 212 from the second conductive region 216.

The vertical transistor 202 has a gate structure 218 that extends around a portion of the channel region 208, which may form a gate all around (GAA) structure.

Advantageously, the techniques provided herein provide a memory cell in which one of the conductive regions is self-aligned with an underlying s/d region and transistor.

FIG. 3A illustrates a schematic of an array 300 of devices 200.1, 200.2 and 200.3. Each of the devices is shown with routing that connects each device to one or the other side of the array 300. For example, a redistribution layer (RDL) may be provided to route connections from each memory cell device, e.g. 200.1 to vertical interconnects provided around the memory cell device on the next level, e.g. 200.2 eventually at a surface above device 200.3. Additionally or alternatively, at least some connections may be routed to the opposite surface, e.g. under device 200.1

FIG. 3B shows an alternative connection scheme. Here, the transistors 200.1, 200.2 and 200.3 are illustrated as abstract cylinders for simplicity. Vertical interconnects 302, 304 and 306 are spread around the array footprint with each set of interconnects for a device extending to directly to that device.

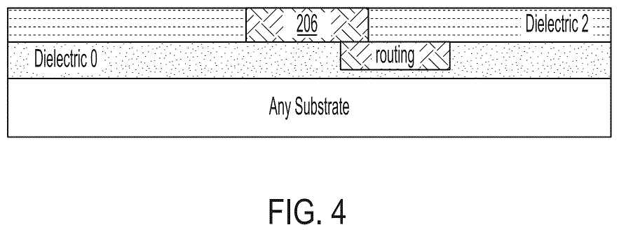

FIGS. 4-16 illustrate an exemplary method of forming a microelectronic device 200. As shown in FIG. 4, a routing layer is formed in a dielectric layer (dielectric 0). This layer will electrically connect the s/d contact 206 to another device in a circuit (not shown). The first s/d contact 206 is then formed on the routing layer within a dielectric layer (Dielectric2).

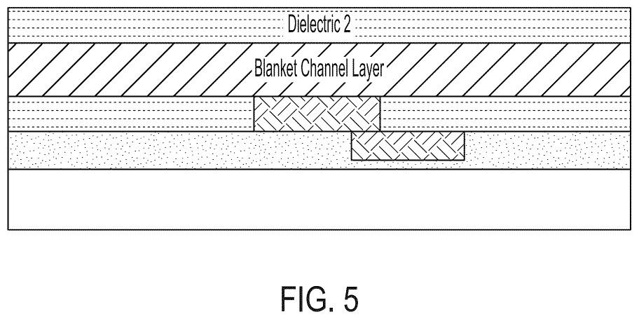

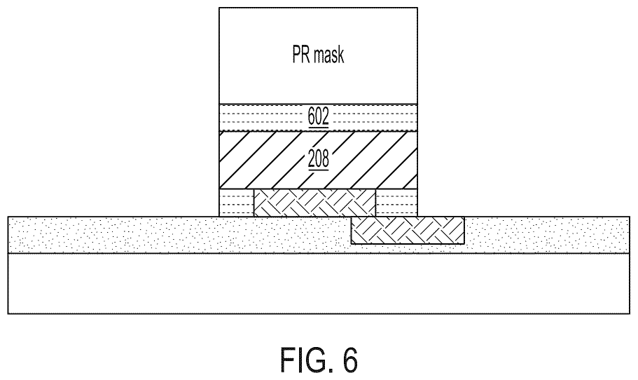

Next, the channel region 208 is formed. As shown in FIG. 5, a blanket channel layer may be deposited. A dielectric layer (Dielectric 2) is formed over the channel layer. Then, as shown in FIG. 6, the channel layer and dielectric layer are patterned using conventional techniques to form the channel region 208 and a dielectric spacer 602.

The channel region may include a semiconductive behaving oxide, a 2D material, an epitaxial semiconductive behaving material, other suitable material, or combinations thereof. Some examples of N-type semiconductive behaving oxides include In₂O₃, SnO₂, InGaZnO, and ZnO. One example of a P-type conductive channel is SnO. Additionally or alternatively, the channel may comprise a 2D material. Some example 2D materials for use in forming the channel include, but are not limited to, WS₂, WSe₂, WTe₂, MoS₂, MoSe₂, MoTe₂, HfS₂, ZrS₂, and TiS₂, GaSe, InSe, phosphorene, and other similar materials. The materials may be annealed during or after the device formation process to recrystallize or grow the crystals and thereby improve electrical characteristics. For the sake of simplicity, the use of semiconductive behaving oxide will be used to illustrate the device.

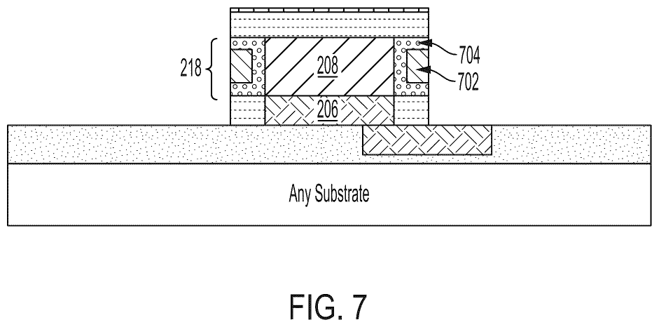

FIG. 7 shows the formation of a gate structure 218. First, an indent etch is performed to remove a portion of the channel region underlying the dielectric spacer to form an opening (not shown). Then, a gate dielectric 702 and gate electrode 704 are formed in the opening to form the gate structure 218. The gate dielectric 702 and gate conductor 704 can be formed by conventional techniques described elsewhere. The gate structure may be formed to surround a portion of the channel region to thereby form a GAA structure.

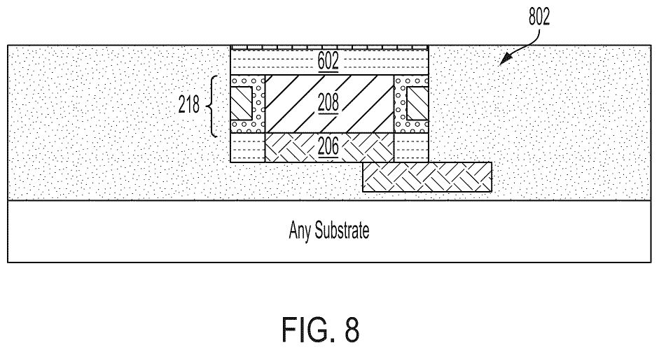

As shown in FIG. 8, a dielectric isolation layer 802 is then formed over the substrate and around the dielectric spacer 602.

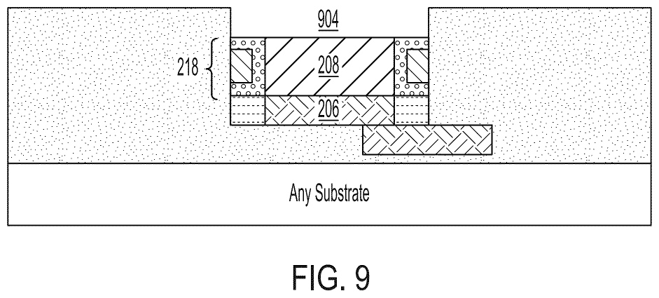

As shown in FIG. 9, the dielectric spacer 602 is then removed leaving a first opening 904 overlying the channel region and the gate structure.

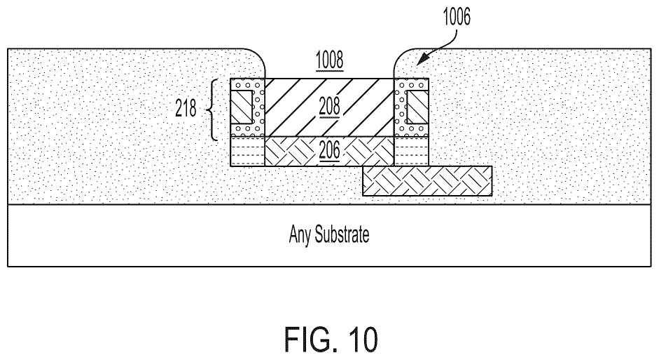

As shown in FIG. 10, an additional spacer 1006 is formed on the dielectric isolation layer to define a second opening 1008 smaller than the first opening 904.

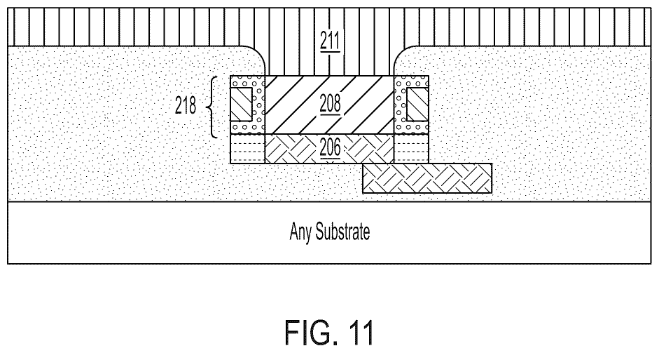

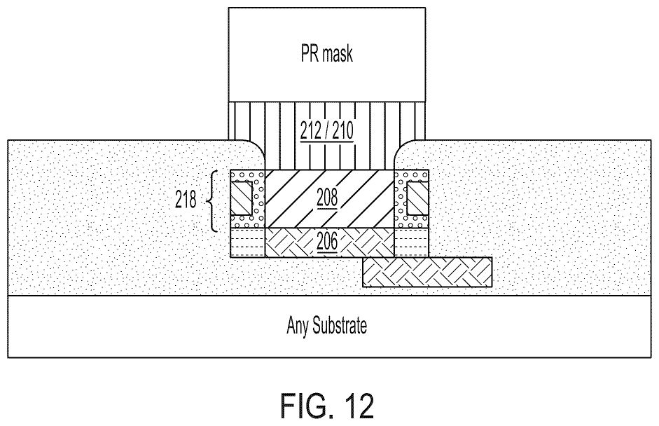

As shown in FIG. 11, a conductive layer 211 is formed in the opening 1008. The conductive layer is then masked and patterned as shown in FIG. 12 to form the s/d contact 210 for the vertical transistor and first conductive region 212 of the capacitor.

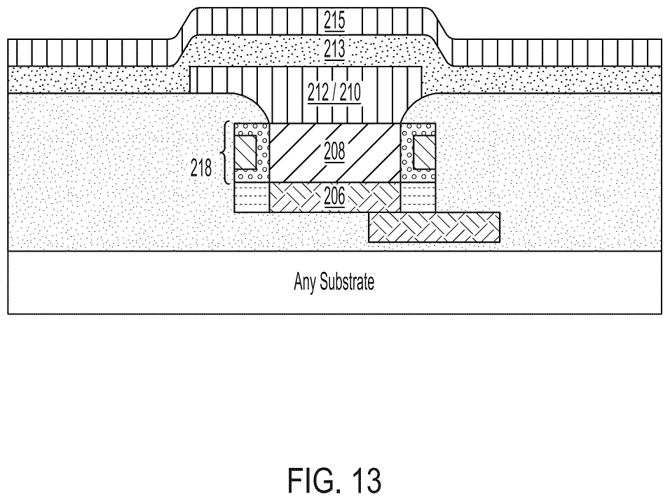

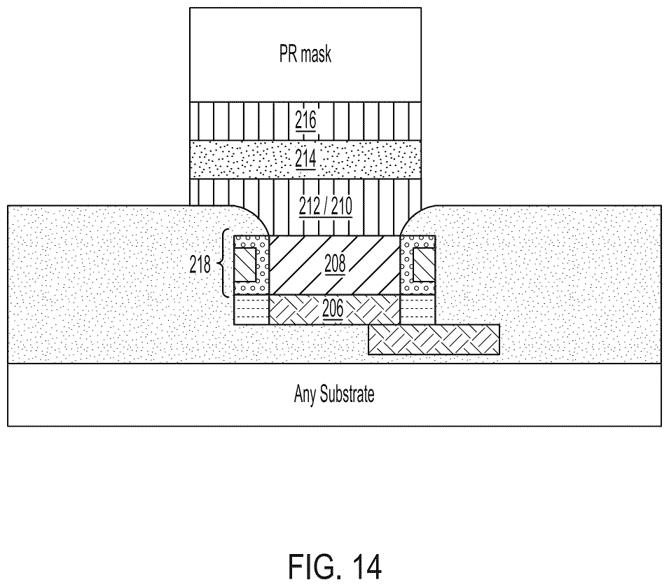

FIG. 13 illustrates the formation of a dielectric layer 213 and conductive layer 215 over the s/d contact 210 and first conductive region 212 of the capacitor. Next, as shown in FIG. 14, the dielectric layer 213 and conductive layer 215 are patterned to form the dielectric region 214 of the capacitor and the other of the two conductive regions 216 of the capacitor. Additionally, portions of the dielectric layer 213 and conductive layer 215 are patterned expose a contact surface of second s/d contact 210 on which to land a vertical electrical connection.

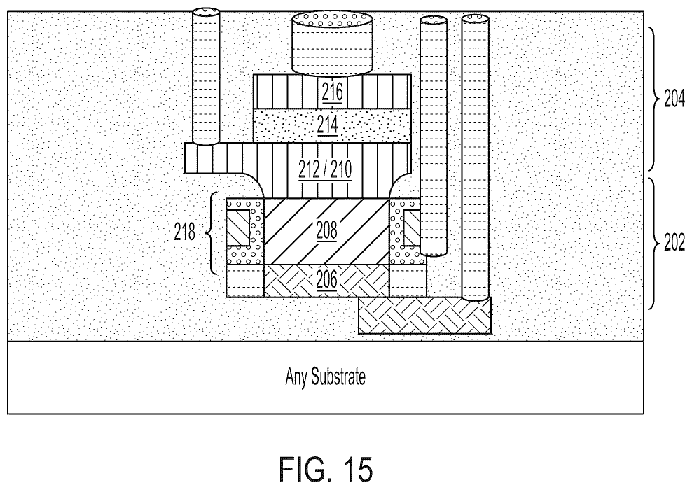

FIG. 15 illustrates additional stages of formation in which a further amount of dielectric material is formed around the capacitor 204 and interconnections are formed according to conventional techniques. Vertical electrical connections are then provided through the further amount of dielectric material with the vertical electrical connection of the second s/d contact region landing on the contact surface of the second s/d contact.

While features of certain embodiments have been described in this disclosure, other embodiments may also exhibit such features and still be within the scope of the claimed invention. It will be appreciated by a person of ordinary skill in the art that particular aspects of the above-disclosed embodiments may be combined with other devices not disclosed herein. In addition, by a person having ordinary skill in the art can make various modifications, alterations, and/or improvements to one or more embodiments disclosed herein, where such modifications, alterations, and/or improvements remain within the scope of the present disclosure and the claims set forth below.

What is claimed is:

1. A microelectronic device comprising:
a vertical transistor having a first source/drain (s/d) region adjacent a substrate, a channel region above the first s/d region, and a second s/d region;
a capacitor having two conductive regions separated by a dielectric region, one of the two conductive regions electrically coupled to the second s/d region.

2. The microelectronic device of claim 1, wherein the vertical transistor has a gate structure that extends around a portion of the channel region to form a gate all around (GAA) structure.

3. A stack of microelectronic devices, each microelectronic device comprising:
a vertical transistor having a first source/drain (s/d) region adjacent a substrate, a channel region above the first s/d region, and a second s/d region;
a capacitor having two conductive regions separated by a dielectric region, one of the two conductive regions electrically coupled to the second s/d region.

4. The microelectronic device of claim 2, wherein the vertical transistor has a gate structure that extends around a portion of the channel to form a gate all around (GAA) structure.

5. A method for forming a microelectronic device comprising:
forming a vertical transistor having a first source/drain (s/d) region adjacent a substrate, a channel region above the first s/d region, and a second s/d region;
forming a capacitor having two conductive regions separated by a dielectric region, one of the two conductive regions electrically coupled to the second s/d region.

6. The method of claim 5, wherein forming a vertical transistor comprises:
forming a first s/d contact of the first s/d region;
forming the channel region over the s/d contact;
forming a gate structure in contact with the channel region; and
forming a second s/d contact of the second s/d region overlying and in contact with the channel region.

7. The method of claim 6, wherein the prior to forming the s/d contact, a routing layer is formed in a dielectric layer to electrically connect the s/d contact to another device in a circuit.

8. The method of claim 6, wherein the channel region comprises a semiconductive behaving oxide.

9. The method of claim 6, wherein the channel region is formed of a material comprising a 2D material.

10. The method of claim 6, wherein the channel region is formed of a material comprising an epitaxial semiconductive behaving material.

11. The method of claim 6, wherein the channel region is formed by a process comprising:
forming a blanket channel layer; and
patterning the channel layer to form the channel region.

12. The method of claim 6, further comprising forming a gate structure surrounding a portion of the channel region to form a GAA structure.

13. The method of claim 6, wherein prior to patterning, a dielectric layer is formed over the channel layer, and the channel layer and dielectric layer are patterned to form the channel region and a dielectric spacer.

14. The method of claim 11, wherein an indent etch is performed to remove a portion of the channel region underlying the dielectric spacer to form an opening, the method further comprising depositing a gate dielectric and gate electrode in the opening to form the gate structure.

15. The method of claim 14, further comprising:
forming a dielectric isolation layer over the substrate and around the dielectric spacer;
removing the dielectric spacer leaving a first opening overlying the channel region;
forming an additional spacer on the dielectric isolation layer to define a second opening smaller than the first opening; and
forming the second s/d contact in the opening.

16. The method of claim 15, wherein forming the capacitor further comprises:
forming a dielectric layer over the second s/d contact, the second s/d contact integral with one of the two conductive regions of the capacitor;
forming a conductive layer over the dielectric layer, and
patterning the dielectric layer and conductive layer to form the dielectric region of the capacitor and the other of the two conductive regions of the capacitor.

17. The method of claim 16, wherein patterning the dielectric layer and conductive layer exposes a portion of the second s/d contact to define a contact surface, the method further comprising:
forming an additional dielectric layer over the exposed second s/d contact and around the dielectric region of the capacitor and the other of the two conductive regions of the capacitor; and
forming electrical connections through the additional dielectric layer, at least one of the electrical connections coupling to the contact surface of the second s/d contact.
